(19) United States
(12) Patent Application Publication
(10) Pub. No.: US 2007/0096123 A1
(43) Pub. Date: May 3, 2007

(54) Nitride semiconductor light-emitting element and manufacturing method thereof

(75) Inventors: Takaaki Utsumi, Mihara-shi (JP); Toshio Hata, Mihara-shi (JP); Daigaku Kimura, Mihara-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/592,478

(22) Filed: Nov. 2, 2006

(30) Foreign Application Priority Data
Nov. 2, 2005 (JP) 2005-319319
Sep. 11, 2006 (JP) 2006-245350

(51) Int. Cl. H01L 33/00

(52) U.S. Cl. 257/86

(57) ABSTRACT

A nitride semiconductor light-emitting element, including a first-conductivity-type nitride semiconductor layer, an active layer, and a second-conductivity-type nitride semiconductor layer successively stacked on a substrate, in which a light extraction surface located above the second-conductivity-type nitride semiconductor layer has a conical or pyramidal projecting portion, as well as a method of manufacturing the nitride semiconductor light-emitting element are provided.

This nonprovisional application is based on Japanese Patent Application Nos. 2005-319319 and 2006-245350 filed with the Japan Patent Office on Nov. 2, 2005 and Sep. 11, 2006, respectively, the entire contents of which are hereby incorporated by reference.

### FIELD OF THE INVENTION

The present invention relates to a nitride semiconductor light-emitting element and a manufacturing method thereof, and more particularly to a nitride semiconductor light-emitting element capable of achieving more efficient extraction of light emitted from an active layer and a manufacturing method thereof

### DESCRIPTION OF THE BACKGROUND ART

A nitride semiconductor light-emitting element has conventionally been formed by successively stacking nitride semiconductor layers on a substrate. Meanwhile, as the index of refraction of the nitride semiconductor layer is very large, total reflection is likely at an interface between the nitride semiconductor layers. For example, if a nitride semiconductor layer is composed of GaN, the nitride semiconductor layer has a large index of refraction of 2.67, and accordingly, its critical angle is extremely small, i.e., 21.9°. Therefore, total reflection of light incident at an angle greater than this angle occurs at the interface between the nitride semiconductor layers, and the light could not be extracted from the nitride semiconductor light-emitting element. It has thus been very difficult to obtain a nitride semiconductor light-emitting element attaining high optical output.

Japanese Patent Laying-Open No. 2003-318443 (Patent Document 1) discloses a nitride semiconductor light-emitting element obtained by successively stacking a reflective layer, a p-type nitride semiconductor layer, an active layer, and an n-type nitride semiconductor layer on a substrate and having a recess in a light extraction surface located above the n-type nitride semiconductor layer.

FIG. 15 shows a schematic perspective view illustrating a nitride semiconductor light-emitting element disclosed in Patent Document 1. In the nitride semiconductor light-emitting element, an electrode 12 for p-type is formed on an Ni substrate 11 formed with Ni plating also serving as an electrode, and a p-type GaN clad layer 13, a p-type AlGaInN carrier block layer 14, an InₓGa₁₋ₓN active layer 15, an Si-doped n-type In_{0.03}Ga_{0.97}N clad layer 16, an Si-doped n-type In_{0.1}Ga_{0.9}N layer 17, and an Si-doped n-type GaN clad layer 18 are successively stacked on electrode 12 for p-type. In addition, an n-type GaN light extraction layer 19 having irregularities is formed on the upper surface of n-type GaN clad layer 18, and an electrode 110 for n-type and a bonding electrode 111 for n-type are successively formed on a part of n-type GaN light extraction layer 19. Here, the irregularities formed in n-type GaN light extraction layer 19 are formed by regrowth of n-type GaN clad layer 18 or polishing.

The nitride semiconductor light-emitting element disclosed in Patent Document 1 has attained high optical output, however, further improvement is desired.

### SUMMARY OF THE INVENTION

An object of the present invention is to provide a nitride semiconductor light-emitting element capable of achieving more efficient extraction of light emitted from an active layer and a manufacturing method thereof.

The present invention is directed to a nitride semiconductor light-emitting element including a first-conductivity-type nitride semiconductor layer, an active layer, and a second-conductivity-type nitride semiconductor layer, that are successively stacked on a substrate, in which a light extraction surface located above the second-conductivity-type nitride semiconductor layer has a conical or pyramidal projecting portion.

Here, in the nitride semiconductor light-emitting element according to the present invention, the substrate composed of at least one selected from the group consisting of Si, SiC, GaAs, ZnO, Cu, W, CuW, Mo, InP, GaN, and sapphire may be employed.

In addition, in the nitride semiconductor light-emitting element according to the present invention, preferably, the projecting portion is implemented as at least one of a cone and a pyramid.

In addition, in the nitride semiconductor light-emitting element according to the present invention, preferably, the projecting portion has a width in a range from at least 0.1 μm to at most 5 μm.

In addition, in the nitride semiconductor light-emitting element according to the present invention, preferably, the projecting portion has a height from a bottom surface to a tip end in a range from at least 0.1 μm to at most 5 μm..

In addition, in the nitride semiconductor light-emitting element according to the present invention, the light extraction surface may be formed in a nitride semiconductor layer above the second-conductivity-type nitride semiconductor layer.

In addition, in the nitride semiconductor light-emitting element according to the present invention, preferably, the nitride semiconductor layer where the light extraction surface is formed has a conductivity type of n.

In addition, in the nitride semiconductor light-emitting element according to the present invention, preferably, an electrode is provided on the nitride semiconductor layer where the light extraction surface is formed, and an interface between the electrode and the nitride semiconductor layer where the light extraction surface is formed is flat.

In addition, in the nitride semiconductor light-emitting element according to the present invention, the light extraction surface may be formed in a translucent electrode layer above the second-conductivity-type nitride semiconductor layer.

In addition, in the nitride semiconductor light-emitting element according to the present invention, ITO or zinc oxide may be used for the translucent electrode layer.

In addition, in the nitride semiconductor light-emitting element according to the present invention, preferably, an electrode is provided on the translucent electrode layer, and an interface between the electrode and the translucent electrode layer is flat.

In addition, the nitride semiconductor light-emitting element according to the present invention may include an intermediate nitride semiconductor layer located between the substrate and the first-conductivity-type nitride semiconductor layer.

In addition, in the nitride semiconductor light-emitting element according to the present invention, preferably, a surface of the intermediate nitride semiconductor layer has a conical or pyramidal projecting portion.

Moreover, the present invention is directed to a method of manufacturing the nitride semiconductor light-emitting element described in any of the paragraphs above, including the step of forming a conical or pyramidal projecting portion on the light extraction surface with reactive ion etching (RIE).

According to the present invention, a nitride semiconductor light-emitting element capable of achieving more efficient extraction of light emitted from the active layer and a manufacturing method thereof can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram illustrating a method of calculating a width of a conical or pyramidal projecting portion in the present invention.

FIG. 2 is a schematic diagram illustrating a method of calculating a height of the conical or pyramidal projecting portion in the present invention.

FIG. 3 is a schematic perspective view illustrating a preferable example of a nitride semiconductor light-emitting element according to the present invention.

FIG. 4 is a schematic cross-sectional view illustrating an example of a sapphire substrate after a buffer layer, an n-type nitride semiconductor layer, an active layer, and a p-type nitride semiconductor layer are successively stacked thereon in the present invention.

FIG. 5 is a schematic cross-sectional view illustrating an example of a state after the sapphire substrate and a p-type Si substrate are joined to each other in the present invention.

FIG. 6 is a schematic cross-sectional view illustrating the step of emitting a laser beam having a prescribed wavelength from the sapphire substrate side in the present invention.

FIG. 7 is a schematic cross-sectional view illustrating a preferable example of a nitride semiconductor light-emitting element according to the present invention.

FIG. 8 is a schematic perspective view illustrating the preferable example of the nitride semiconductor light-emitting element according to the present invention.

FIGS. 9 to 14 are schematic cross-sectional views illustrating a part of a preferable example of a method of manufacturing the nitride semiconductor light-emitting element shown in FIG. 8.

FIG. 15 is a schematic perspective view of an example of a conventional nitride semiconductor light-emitting element.

### DESCRIPTION OF THE PREFERRED EMBODIMENTS

An embodiment of the present invention will be described hereinafter. In the drawings of the present invention, it is assumed that the same reference characters represent the same or corresponding elements.

The present invention is characterized by a nitride semiconductor light-emitting element including a first-conductivity-type nitride semiconductor layer, an active layer, and a second-conductivity-type nitride semiconductor layer, that are successively stacked on a substrate, in which a light extraction surface located above the second-conductivity-type nitride semiconductor layer has a conical or pyramidal projecting portion. The present invention was completed as a result of dedicated study by the present inventors, and the present inventors have found that a light extraction surface having a conical or pyramidal projecting portion of which cross-section has a tip end in an acute-angle is formed as in the present invention so that light emitted from an active layer can more efficiently be extracted, although light emitted from the active layer can efficiently be extracted also when a cross-section of irregularities in the light extraction surface has a tip end in an obtuse angle as in Patent Document 1. If the cross-section of irregularities in the light extraction surface has a tip end in an obtuse angle not smaller than 90° as in Patent Document 1, the light once totally reflected by the irregularities is again totally reflected by the irregularities, and finally the light returns to the inside of the nitride semiconductor light-emitting element, whereby efficiency in light extraction to the outside of the nitride semiconductor light-emitting element becomes poor. On the other hand, if the light extraction surface has a conical or pyramidal projecting portion of which cross-section has a tip end in an acute angle smaller than 90°, probability of total reflection of light again by the conical or pyramidal projecting portion, that has once been totally reflected by that projecting portion, is extremely low. Therefore, it is considered that the light emitted from the active layer can further efficiently be extracted.

Here, in the present invention, for example, a substrate composed of at least one selected from the group consisting of Si, SiC, GaAs, ZnO, Cu, W, CuW, Mo, InP, GaN, and sapphire may be employed as the substrate. Among others, from a point of view of greater light extraction area as a result of decrease in the number of electrodes formed on the light extraction surface, a conductive substrate is preferably used as the substrate. From the group above, more preferably, a conductive Si substrate or a conductive SiC substrate is employed. From a point of view of low cost and high workability, a conductive Si substrate is further preferably employed.

In addition, in the present invention, preferably, the conical or pyramidal projecting portion is implemented as at least one of a cone and a pyramid. In this case, extraction of light from the light extraction surface, the light being emitted from the active layer, tends to be more uniform.

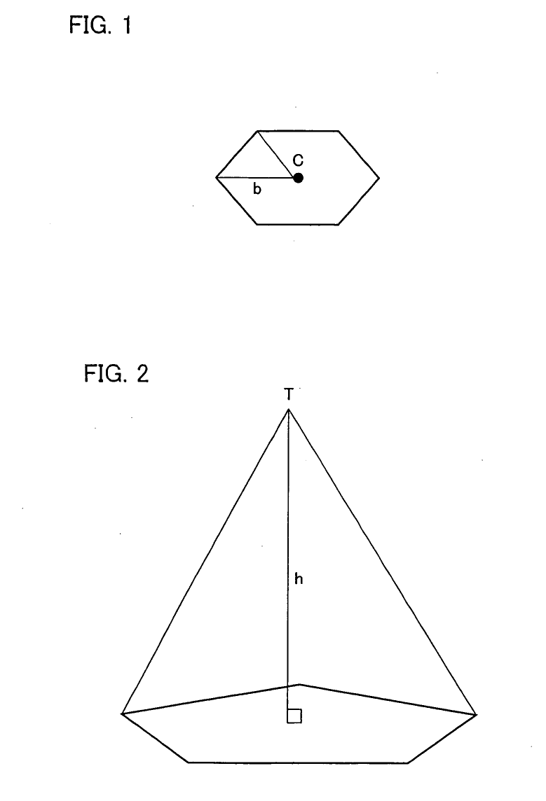

In addition, in the present invention, the conical or pyramidal projecting portion has a width preferably in a range from at least 0.1 μm to at most 5 μm, and more preferably in a range from at least 1 μm to at most 3 μm. If the conical or pyramidal projecting portion formed in the light extraction surface has a width smaller than 0.1 μm and a width larger than 5 μm, forming of the conical or pyramidal projecting portion tends to be difficult. On the other hand, if the conical or pyramidal projecting portion formed in the light extraction surface has a width in a range from at least 1 μm to at most 3 μm, forming of the conical or pyramidal projecting portion tends to be easier. It is noted that the width of the conical or pyramidal projecting portion is defined as follows. For example, as shown in FIG. 1, a line is drawn from central point C of the bottom surface of the conical or pyramidal projecting portion to each vertex thereof, and the width is set to a length twice as long as b representing a length of a longest line among these drawn lines. If the bottom surface of the conical projecting portion has a circular shape, the diameter of that circle is set as the width of the conical projecting portion. If the bottom surface of the conical projecting portion has an oval shape, the major axis of the oval is set as the width of the conical projecting portion.

In addition, in the present invention, the conical or pyramidal projecting portion has a height from the bottom surface to the tip end preferably in a range from at least 0.1 μm to at most 5 μm, and more preferably in a range from at least 0.4 μm to at most 2 μm. If the conical or pyramidal projecting portion formed in the light extraction surface has a height from the bottom surface to the tip end smaller than 0.1 μm, control of working accuracy of the projecting portion tends to be difficult, the height of the projecting portion from the bottom surface to the tip end is more likely to be shorter than emission wavelength, and efficiency in extraction of light to the outside is less likely to improve. On the other hand, if the conical or pyramidal projecting portion has a height from the bottom surface to the tip end greater than 5 μm, forming of the projecting portion tends to be difficult, and the light extracted from the light extraction surface may be extracted in dots, not in a uniform plane. Meanwhile if the conical or pyramidal projecting portion formed in the light extraction surface has a height from the bottom surface to the tip end in a range from at least 0.4 μm to at most 2 μm, control of working accuracy of the projecting portion tends to be easy, the light can be extracted in a uniform plane, and efficiency in extraction of light to the outside tends to improve. It is noted that the height of the conical or pyramidal projecting portion from the bottom surface to the tip end is defined as h representing a length of a normal from tip end T to the bottom surface of the conical or pyramidal projecting portion, for example, as shown in FIG. 2.

In addition, in the present invention, the light extraction surface may be formed in a nitride semiconductor layer above the second-conductivity-type nitride semiconductor layer. If the light extraction surface is formed in the nitride semiconductor layer, light absorption in the nitride semiconductor layer where the light extraction surface is formed is minimized, and therefore, efficiency in extraction of light to the outside tends to improve.

In addition, in the present invention, preferably, the nitride semiconductor layer where the light extraction surface is formed has a conductivity type of n. If the nitride semiconductor layer where the light extraction surface is formed has a conductivity type of n, the nitride semiconductor layer where the light extraction surface is formed can have a larger thickness than in a case where the nitride semiconductor layer where the light extraction surface is formed has a conductivity type of p. Accordingly, the fed current sufficiently spreads in the active layer, and luminance of the nitride semiconductor light-emitting element according to the present invention tends to improve.

In addition, in the present invention, the light extraction surface may be formed in a translucent electrode layer above the second-conductivity-type nitride semiconductor layer. In this case, though slight light absorption occurs in the translucent electrode layer where the light extraction surface is formed, spread of the fed current in the translucent electrode layer tends to improve. Here, in the present invention, a translucent electrode layer composed, for example, of ITO (Indium Tin Oxide) or zinc oxide may be used as the translucent electrode layer. Among others, ITO which is more likely to attain excellent electric characteristic and translucency is preferably employed as the translucent electrode layer used in the present invention.

If an electrode is formed in the nitride semiconductor layer or the translucent electrode layer where the light extraction surface is formed, an interface between the electrode and the light extraction surface is preferably flat. If the interface between the electrode and the light extraction surface is not flat, a wire bonded to the electrode tends to be detached during packaging, or satisfactory contact may not be achieved. Here, the concept “flat” in the present invention encompasses not only a completely flat state with no irregularities but also a state with such irregularities as not particularly causing an actual problem.

Moreover, in the nitride semiconductor light-emitting element of the present invention, the conical or pyramidal projecting portion is preferably formed with RIE. In this case, it is not necessary to form a fine mask pattern, and in addition, damage to the nitride semiconductor layer where the light extraction surface is formed is less than in a method such as polishing. Further, it has been found that a surface shape after etching with RIE is considerably different between the case where the p-type nitride semiconductor layer is etched with RIE and the case where the n-type nitride semiconductor layer is etched with RIE. Specifically, it has been confirmed that, if the p-type nitride semiconductor layer is etched with RIE, the p-type nitride semiconductor layer is uniformly etched in its surface, whereas if the n-type nitride semiconductor layer is etched with RIE, the conical or pyramidal projecting portion in the present invention is formed on the surface of the n-type nitride semiconductor layer after etching with RIE.

In addition, in the present invention, a material obtained by diffusing a p-type or n-type dopant in a nitride-based semiconductor, of which composition is expressed, for example, by the formula In_{y}Al_{z}Ga_{1-y-z}N (0≦y≦1, 0≦z≦1, 0≦y+z≦1), may be used for the first-conductivity-type nitride semiconductor layer.

In addition, in the present invention, a material obtained by diffusing an n-type or p-type dopant in a nitride-based semiconductor, of which composition is expressed, for example, by the formula In_{w}AlₓGa_{1-w-x}N (0≦w≦1, 0≦x1, 0≦w+x≦1), may be used for the second-conductivity-type nitride semiconductor layer.

It is noted that, in the present invention, if the first-conductivity-type nitride semiconductor layer has a conductivity type of p, the second-conductivity-type nitride semiconductor layer has a conductivity type of n, and if the first-conductivity-type nitride semiconductor layer has a conductivity type of n, the second-conductivity-type nitride semiconductor layer has a conductivity type of p.

In addition, in the present invention, a conventionally known material may be used as the p-type dopant, and for example, at least one selected from the group consisting of Mg, Zn, Cd, and Be may be used. Moreover, in the present invention, a conventionally known material may be used as the n-type dopant, and for example, at least one selected from the group consisting of Si, O, Cl, S, C, and Ge may be used.

In addition, in the present invention, a nitride-based semiconductor, of which composition is expressed, for example, by the formula InᵤAlᵥGa₁₋ᵤ₋ᵥN (0≦u≦1, 0≦v≦1, 0≦u+v≦1), may be used for the active layer. Further, the active layer used in the present invention may have either an MQW (multiple quantum well) structure or an SQW (single quantum well) structure.

In addition, in the present invention, a conventionally known method may be used as a method of stacking the first-conductivity-type nitride semiconductor layer, the second-conductivity-type nitride semiconductor layer, and the active layer. For example, LPE (liquid phase epitaxy), VPE (vapor phase epitaxy), MOCVD (metal-organic chemical vapor deposition), MBE (molecular beam epitaxy), gas source MBE, or combination thereof may be employed.

In addition, the nitride semiconductor light-emitting element according to the present invention may naturally include a reflective layer, a diffusion-preventing layer or the like.

(First Embodiment)

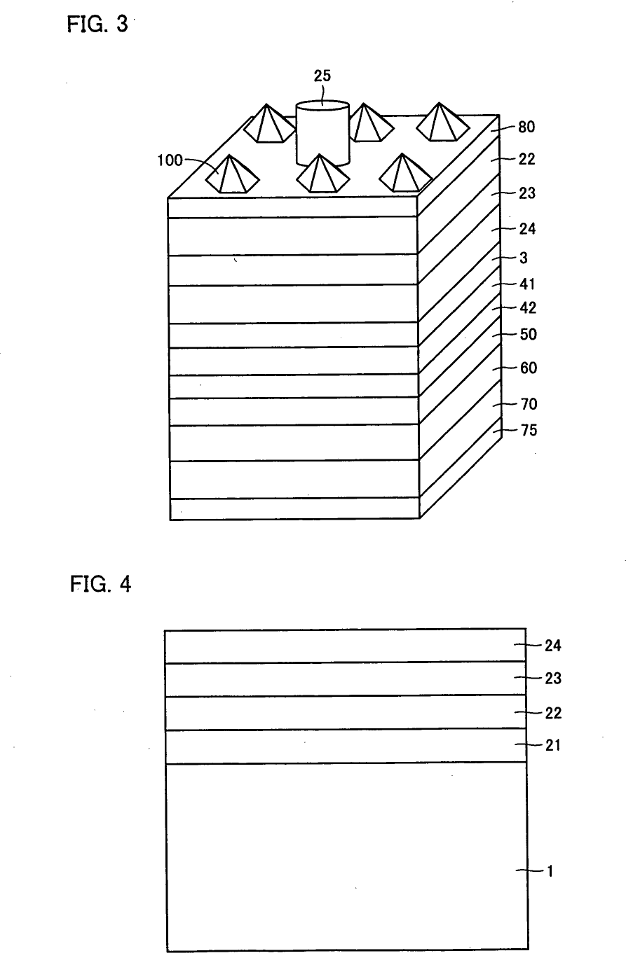

FIG. 3 shows a schematic perspective view illustrating a preferable example of a nitride semiconductor light-emitting element according to the present invention. In the nitride semiconductor light-emitting element of the present invention, a p-type Si substrate 70, a second adhesion metal layer 60, a first adhesion metal layer 50, a diffusion-preventing layer 42, a reflective layer 41, an ohmic electrode 3, a p-type nitride semiconductor layer 24 composed of AlₐGa₁₋ₐN (0≦a≦1) doped with a p-type dopant, an active layer 23 composed on non-doped In_{b}Ga_{1-b}N (0<b<1), and an n-type nitride semiconductor layer 22 composed of Al_{c}Ga_{1-c}N (0≦c≦1) doped with an n-type dopant are successively stacked on an ohmic electrode 75 for p-type in this order, and a nitride semiconductor layer 80 composed of n-type Al_{c}Ga_{1-c}N (0≦c≦1) is formed on n-type nitride semiconductor layer 22. The surface of nitride semiconductor layer 80 serves as the light extraction surface, and the light extraction surface has a plurality of projecting portions 100 implemented by a six-sided pyramid. In addition, an ohmic electrode 25 for n-type is formed on nitride semiconductor layer 80.

A preferable example of a method of manufacturing the nitride semiconductor light-emitting element according to the present invention will be described with reference to FIGS. 4 to 6. Initially, as shown in the schematic cross-sectional view in FIG. 4, a buffer layer 23 composed of GaN, n-type nitride semiconductor layer 22, active layer 23, and p-type nitride semiconductor layer 24 are successively stacked on sapphire substrate 1 with MOCVD.

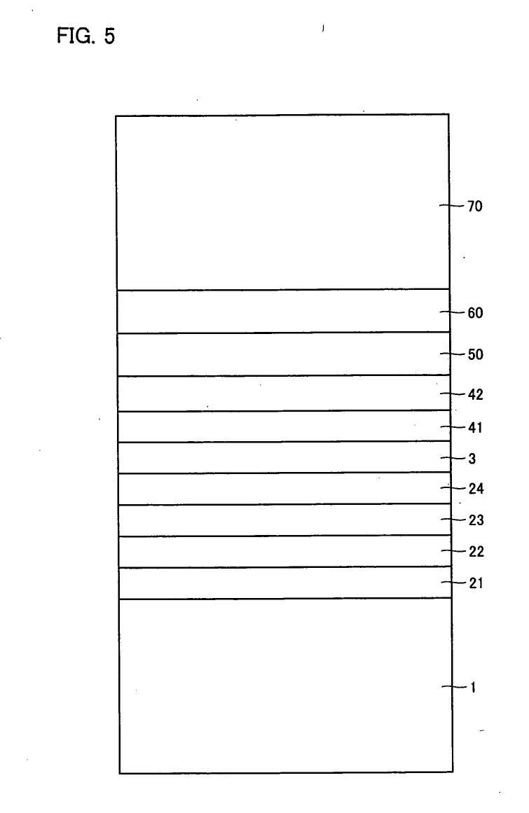

Then, as shown in FIG. 5, a Pd layer is vapor-deposited on p-type nitride semiconductor layer 24 as ohmic electrode 3 to a thickness of 3 nm with EB vapor deposition, and thereafter, using sputtering, an Ag—Nd layer is deposited as reflective layer 41 to a thickness of 150 nm and an Ni—Ti layer is deposited thereon successively as diffusion-preventing layer 42 to a thickness of 100 nm. Then, an Au layer is deposited on diffusion-preventing layer 42 as first adhesion metal layer 50 to a thickness of 3 nm.

On the other hand, p-type Si substrate 70 substantially as large as sapphire substrate 1 is employed as the conductive substrate, and second adhesion metal layer 60 containing Ti, Au and AuSn is formed on p-type Si substrate 70 to a thickness of 3 μm.

Then, as shown in the schematic cross-sectional view in FIG. 5, sapphire substrate 1 on which a plurality of layers up to first adhesion metal layer 50 are stacked and p-type Si substrate 70 on which second adhesion metal layer 60 is formed are joined to each other by heated compression bonding of first adhesion metal layer 50 and second adhesion metal layer 60. Here, preferably, sapphire substrate 1 and p-type Si substrate 70 are joined in parallel to each other. Sapphire substrate 1 and p-type Si substrate 70 are joined in parallel to each other, so that sapphire substrate 1 tends to be removed appropriately from the entire surface in the process of removing sapphire substrate 1 which will be described later.

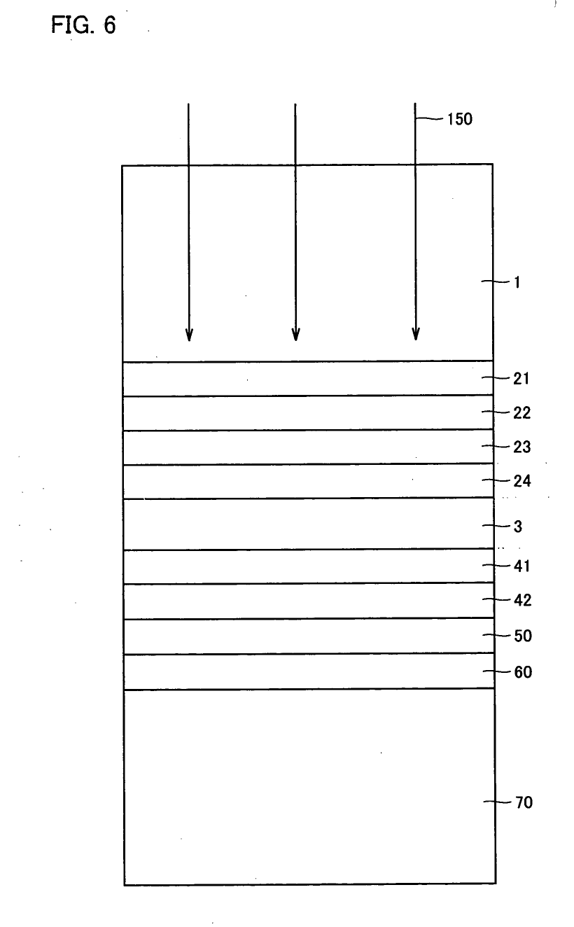

Thereafter, as shown in the schematic cross-sectional view in FIG. 6, a laser beam 150 having a prescribed wavelength is emitted from the side of sapphire substrate 1 to melt buffer layer 23, thus removing sapphire substrate 1. For example, a YAG-THG laser beam (third harmonic of YAG laser beam: wavelength of 355 nm) may be used as such laser beam 150. If sapphire substrate 1 cannot completely be removed only with emission of laser beam 150, sapphire substrate 1 may be removed by being immersed in extremely hot water at a temperature around 100° C. Thereafter, a wafer after removal of sapphire substrate 1 is immersed in an HCl solution so as to remove a damaged layer or an oxidized layer, thereby cleaning the surface of the wafer.

Thereafter, the surface of n-type nitride semiconductor layer 22 is etched with RIE, so that nitride semiconductor layer 80 having projecting portion 100 implemented by a six-sided pyramid shown in FIG. 3 is formed. Here, as nitride semiconductor layer 80 has a hexagonal structure, projecting portion 100 is in a shape of a six-sided pyramid. In addition, by protecting a portion directly under subsequently formed n-type ohmic electrode 25 with a photoresist, the interface between the surface of nitride semiconductor layer 80 and n-type ohmic electrode 25 can be flat. Moreover, projecting portion 100 has a width preferably in a range from at least 0.1 μm to at most 5 μm, and more preferably in a range from at least 1 μm to at most 3 μm. In addition, projecting portion 100 has a height from the bottom surface to the tip end preferably in a range from at least 0.1 μm to at most 5 μm, and more preferably in a range from at least 0.4 μm to at most 2 μm.

In succession, a Ti—Al layer is formed like a pad as n-type ohmic electrode 25 to a thickness of 20 nm. On the other hand, a Ti—Al layer is formed as ohmic electrode 75 for p-type on the entire surface of p-type Si substrate 70 to a thickness of 750 nm.

Finally, p-type Si substrate 70 is divided into squares having a side of 350 μm by dicing, thus obtaining the nitride semiconductor light-emitting element of the present invention shown in FIG. 3.

In the present embodiment, though the light extraction surface having the projecting portion in a shape of a six-sided pyramid is formed, instead of or in addition to the six-sided pyramid, for example, a projecting portion in a shape of at least one of a triangular pyramid, a quadrangular pyramid and a cone may be formed. Therefore, for example, a projecting portion in a shape formed as follows should be formed as the conical or pyramidal projecting portion in the present invention. Specifically, a straight line connecting one point on an enclosing line formed by a curve and/or straight lines on a plane with a certain point outside that plane is drawn, and one point on the enclosed line is moved on the entire enclosed line with the certain point outside the plane being fixed, whereby a surface is drawn by the trace of the aforementioned straight line. This surface and the plane enclosed by the enclosing line above form the projecting portion.

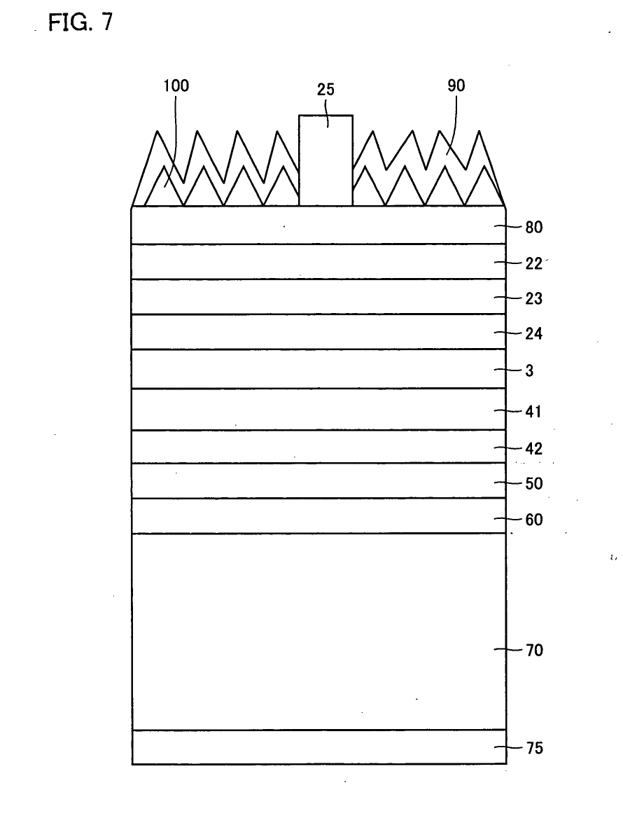

(Second Embodiment) FIG. 7 shows a schematic cross-sectional view illustrating a preferable example of a nitride semiconductor light-emitting element according to the present invention. The nitride semiconductor light-emitting element shown in FIG. 7 is characterized in that a translucent electrode layer 90 is formed on nitride semiconductor layer 80.

In the method of manufacturing the nitride semiconductor light-emitting element, the process steps until the light extraction surface is formed on nitride semiconductor layer 80 can be performed as in the first embodiment. Then, after the surface of n-type nitride semiconductor layer 22 is etched with RIE to form nitride semiconductor layer 80 having projecting portion 100 in a shape of a six-sided pyramid, translucent electrode layer 90 composed of ITO is formed on the surface of nitride semiconductor layer 80 with sputtering to a thickness of 500 nm. Thereafter, ohmic electrode 25 for n-type is formed on the surface of nitride semiconductor layer 80 as in the first embodiment above. Here, projecting portion 100 has a width of 1.0 μm, and a height from the bottom surface to the tip end of 3.0 μm.

In the nitride semiconductor light-emitting element, if nitride semiconductor layer 80 has a thickness sufficiently greater than 500 nm, irregularities on the light extraction surface of nitride semiconductor layer 80 tend to appear also in translucent electrode layer 90, and efficiency in extraction of light to the outside is also as, excellent as in the first embodiment. In addition, if translucent electrode layer 90 is formed on the entire surface of nitride semiconductor layer 80, the current fed from ohmic electrode 25 for n-type also spreads in translucent electrode layer 90. Therefore, the nitride semiconductor light-emitting element attaining further higher luminance can be obtained.

Here, if the thickness of translucent electrode layer 90 is greater than the height of projecting portion 100 from the bottom surface to the tip end, the surface of translucent electrode layer 90 can be flat. On the other hand, nitride semiconductor layer 80 has index of refraction nl of approximately 2.6, translucent electrode layer 90 has index of refraction n2 of approximately 2.1, a sealing resin used for packaging has index of refraction n3 of approximately 1.6, and relation of n1>n2>n3 is satisfied. Therefore, total reflection at such interface is less. In addition, as the surface of nitride semiconductor layer 80 serves as the light extraction surface having projecting portion 100 in a shape of a six-sided pyramid, total reflection at the interface between nitride semiconductor layer 80 and translucent electrode layer 90 is less. Therefore, efficiency in extraction of light to the outside is improved also in the nitride semiconductor light-emitting element shown in FIG. 7.

(Third Embodiment)

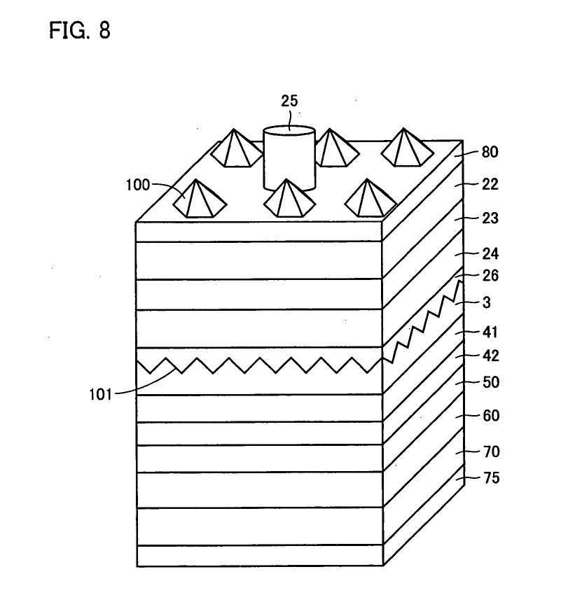

FIG. 8 shows a schematic perspective view illustrating a preferable example of a nitride semiconductor light-emitting element according to the present invention. The nitride semiconductor light-emitting element shown in FIG. 8 is characterized in that an n-type intermediate nitride semiconductor layer 26 located between p-type Si substrate 70 and p-type nitride semiconductor layer 24 is provided and the surface of intermediate nitride semiconductor layer 26 on the side of p-type Si substrate 70 has a conical or pyramidal projecting portion 101.

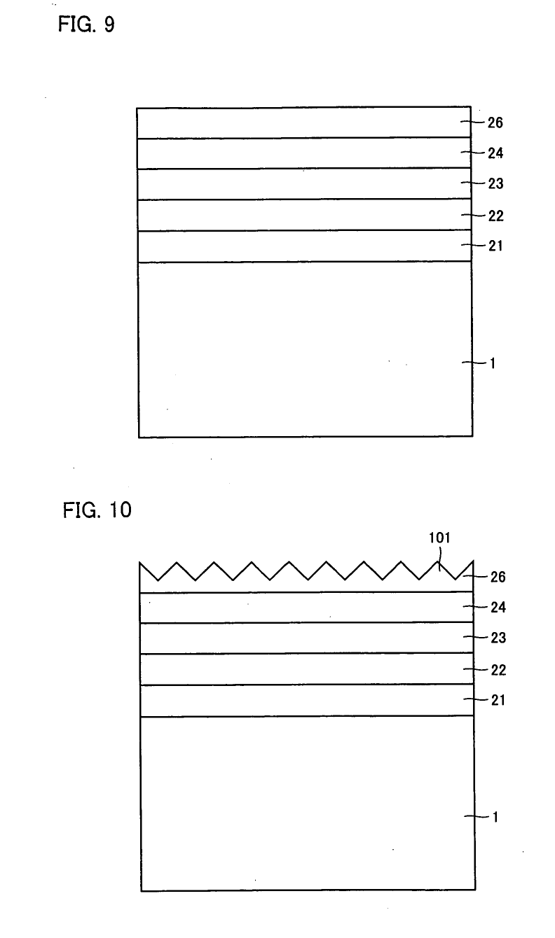

A preferable example of a method of manufacturing the nitride semiconductor light-emitting element according to the present invention structured as shown in FIG. 8 will be described with reference to FIGS. 9 to 14. Initially, as shown in the schematic cross-sectional view in FIG. 9, buffer layer 23 composed of GaN, n-type nitride semiconductor layer 22, active layer 23, p-type nitride semiconductor layer 24, and n-type intermediate nitride semiconductor layer 26 are successively stacked on sapphire substrate 1 with MOCVD.

Then, as shown in the schematic cross-sectional view in FIG. 10, the surface of intermediate nitride semiconductor layer 26 is etched with RIE, thus forming projecting portion 101 in a shape of a six-sided pyramid on the surface of intermediate nitride semiconductor layer 26.

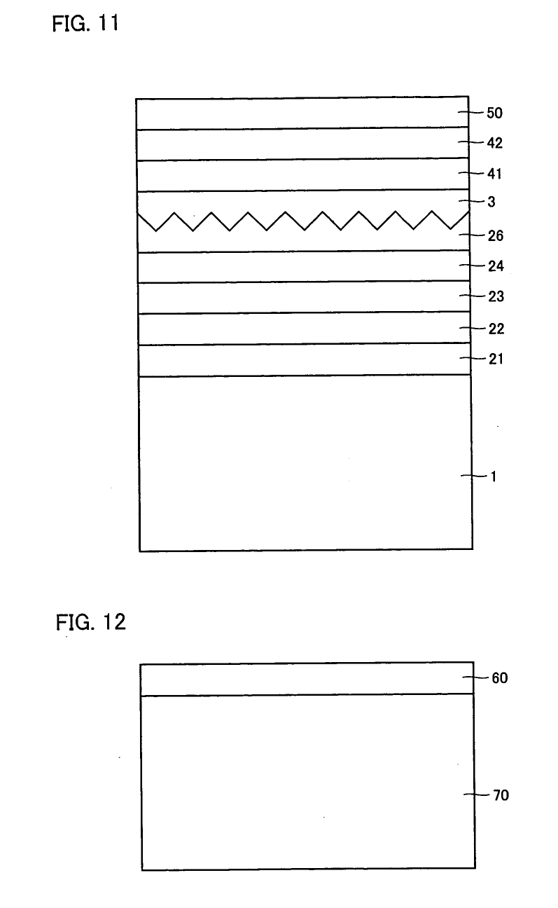

In succession, as shown in the schematic cross-sectional view in FIG. 11, a Pd layer is vapor-deposited as ohmic electrode 3, for example, to a thickness of 3 nm with EB vapor deposition on the surface of intermediate nitride semiconductor layer 26 where projecting portion 101 in a shape of a six-sided pyramid is formed, and thereafter, using sputtering, an Ag—Nd layer is deposited as reflective layer 41, for example, to a thickness of 150 nm and an Ni—Ti layer is deposited thereon successively as diffusion-preventing layer 42, for example, to a thickness of 100 nm. Then, an Au layer is deposited on diffusion-preventing layer 42 as first adhesion metal layer 50, for example, to a thickness of 3 nm.

On the other hand, as shown in the schematic cross-sectional view in FIG. 12, p-type Si substrate 70 substantially as large as sapphire substrate 1 is employed as the conductive substrate, and second adhesion metal layer 60 containing Ti, Au and AuSn is formed on p-type Si substrate 70, for example, to a thickness of 3 μm.

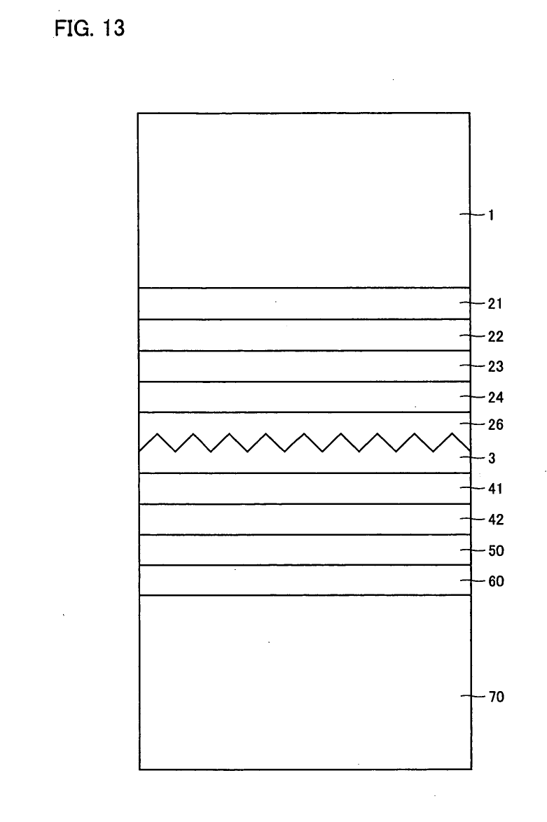

Then, as shown in the schematic cross-sectional view in FIG. 13, sapphire substrate 1 on which a plurality of layers up to first adhesion metal layer 50 are stacked and p-type Si substrate 70 on which second adhesion metal layer 60 is formed are joined to each other by heated compression bonding of first adhesion metal layer 50 and second adhesion metal layer 60.

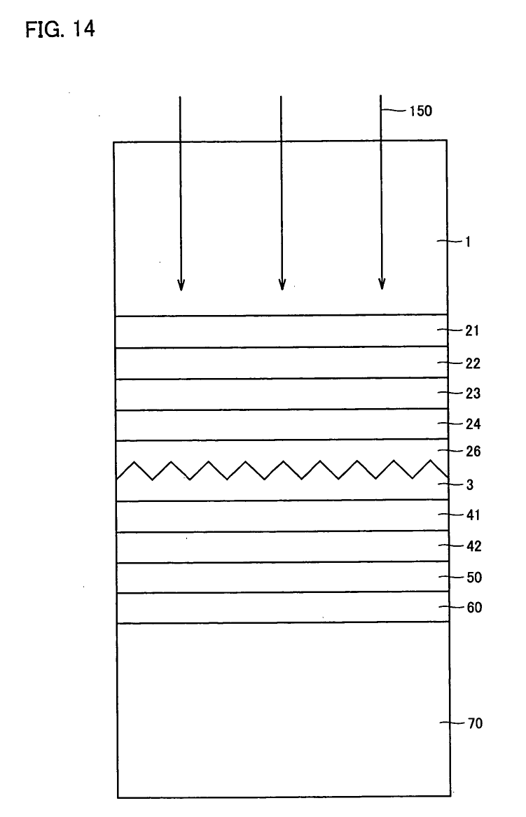

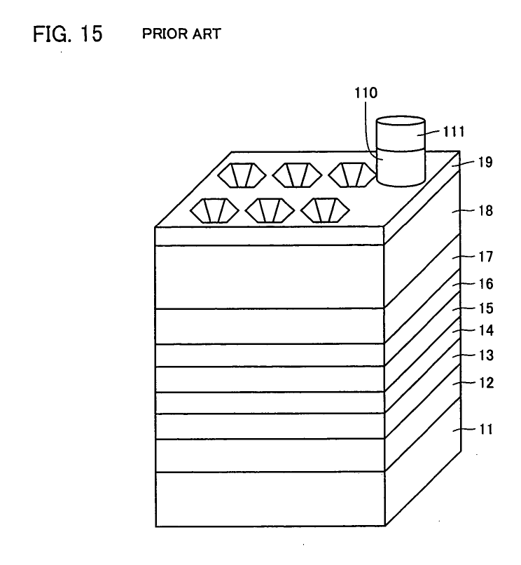

Thereafter, as shown in the schematic cross-sectional view in FIG. 14, laser beam 150 having a prescribed wavelength is emitted from the side of sapphire substrate 1 to melt buffer layer 23, thus removing sapphire substrate 1. For example, a YAG-THG laser beam (third harmonic of YAG laser beam: wavelength of 355 nm) may be used as such laser beam 150. If sapphire substrate 1 cannot completely be removed only with emission of laser beam 150, sapphire substrate 1 may be removed by being immersed in extremely hot water at a temperature around 100° C. Thereafter, a wafer after removal of sapphire substrate 1 is immersed in an HCl solution so as to remove a damaged layer or an oxidized layer, thereby cleaning the surface of the wafer.

Thereafter, the surface of n-type nitride semiconductor layer 22 is etched with RIE, so that nitride semiconductor layer 80 having projecting portion 100 implemented by a six-sided pyramid shown in FIG. 8 is formed. In addition, by protecting a portion directly under subsequently formed n-type ohmic electrode 25 with a photoresist, the interface between the surface of nitride semiconductor layer 80 and n-type ohmic electrode 25 can be flat. Moreover, projecting portion 100 has a width preferably in a range from at least 0.1 μm to at most 5 μm and more preferably in a range from at least 1 μm to at most 3 μm. In addition, projecting portion 100 has a height from the bottom surface to the tip end preferably in a range from at least 0.1 μm to at most 5 μm, and more preferably in a range from at least 0.4 μm to at most 2 μm.

In succession, a Ti—Al layer is formed like a pad as n-type ohmic electrode 25, for example, to a thickness of 20 nm. On the other hand, a Ti—Al layer is formed as ohmic electrode 75 for p-type on the entire surface of p-type Si substrate 70, for example, to a thickness of 750 nm.

Finally, p-type Si substrate 70 is divided into squares having a side, for example, of 350 μm by dicing, thus obtaining the nitride semiconductor light-emitting element of the present invention shown in FIG. 8.

In the nitride semiconductor light-emitting element structured as shown in FIG. 8, efficiency in extraction to the outside of light that proceeds upward (direction of nitride semiconductor layer 80) out of light emitted from active layer 23 can be improved by conical or pyramidal projecting portion 100 formed on the light extraction surface implemented by the surface of nitride semiconductor layer 80, and also efficiency in extraction to the outside of light that proceeds downward (direction of p-type Si substrate 70) out of light emitted from active layer 23 can be improved by conical or pyramidal projecting portion 101 extending in a direction opposite to that of conical or pyramidal projecting portion 100. Therefore, in the nitride semiconductor light-emitting element structured as shown in FIG. 8, light emitted from active layer 23 can further efficiently be extracted.

It is noted that an n-type nitride semiconductor or the like obtained by diffusing an n-type dopant in a nitride-based semiconductor, of which composition is expressed, for example, by the formula InₛAlₜGa₁₋ₛ₋ₜN (0≦s≦1, 0≦t≦1, 0≦s+t≦1), may be used for intermediate nitride semiconductor layer 26.

In addition, in the embodiment above, from a point of view of lower operation voltage of the nitride semiconductor light-emitting element as a result of lowering in resistivity of n-type intermediate nitride semiconductor layer 26,. n-type intermediate nitride semiconductor layer 26 preferably includes an n-type nitride semiconductor layer having a carrier density in a range from at least 3×10¹⁸/cm³ to at most 1×10¹⁹/cm³.

According to the present invention, a nitride semiconductor light-emitting element capable of achieving more efficient extraction of light emitted from the active layer and a manufacturing method thereof can be provided.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A nitride semiconductor light-emitting element comprising:
a first-conductivity-type nitride semiconductor layer;
an active layer; and
a second-conductivity-type nitride semiconductor layer, that are successively stacked on a substrate; wherein
a light extraction surface located above said second-conductivity-type nitride semiconductor layer has a conical or pyramidal projecting portion.

2. The nitride semiconductor light-emitting element according to claim 1, wherein
said substrate is composed of at least one selected from the group consisting of Si, SiC, GaAs, ZnO, Cu, W, CuW, Mo, InP, GaN, and sapphire.

3. The nitride semiconductor light-emitting element according to claim 1, wherein
said projecting portion is implemented as at least one of a cone and a pyramid.

4. The nitride semiconductor light-emitting element according to claim 1, wherein
said projecting portion has a width in a range from at least 0.1 μm to at most 5 μm.

5. The nitride semiconductor light-emitting element according to claim 1, wherein
said projecting portion has a height from a bottom surface to a tip end in a range from at least 0.1 μm to at most 5 μm.

6. The nitride semiconductor light-emitting element according to claim 1, wherein
said light extraction surface is formed in a nitride semiconductor layer above said second-conductivity-type nitride semiconductor layer.

7. The nitride semiconductor light-emitting element according to claim 6, wherein
said nitride semiconductor layer where said light extraction surface is formed has a conductivity type of n.

8. The nitride semiconductor light-emitting element according to claim 7, wherein
an electrode is provided on said nitride semiconductor layer where said light extraction surface is formed, and an interface between said electrode and said nitride semiconductor layer where said light extraction surface is formed is flat.

9. The nitride semiconductor light-emitting element according to claim 1, wherein
said light extraction surface is formed in a translucent electrode layer above said second-conductivity-type nitride semiconductor layer.

10. The nitride semiconductor light-emitting element according to claim 9, wherein
said translucent electrode layer is composed of ITO or zinc oxide.

11. The nitride semiconductor light-emitting element according to claim 9, wherein
an electrode is provided on said translucent electrode layer, and an interface between said electrode and said translucent electrode layer is flat.

12. The nitride semiconductor light-emitting element according to claim 1, further comprising an intermediate nitride semiconductor layer located between said substrate and said first-conductivity-type nitride semiconductor layer.

13. The nitride semiconductor light-emitting element according to claim 12, wherein
a surface of said intermediate nitride semiconductor layer has a conical or pyramidal projecting portion.

14. A method of manufacturing the nitride semiconductor light-emitting element according to claim 1, comprising the step of forming a conical or pyramidal projecting portion on said light extraction surface with reactive ion etching.
